(19) United States
(12) Patent Application Publication
(10) Pub. No.: US 2020/0040444 A1
(43) Pub. Date: Feb. 6, 2020

(54) PLASMA SPRAY SYSTEMS AND METHODS

(71) Applicant: Lyten, Inc., Sunnyvale, CA (US)

(72) Inventors: Michael W. Stowell, Sunnyvale, CA (US); Daniel Cook, Woodside, CA (US); Joe Griffith Cruz, San Jose, CA (US); Thomas Riso, Elizabeth, CO (US)

(73) Assignee: Lyten, Inc., Sunnyvale, CA (US)

(21) Appl. No.: 16/460,177

(22) Filed: Jul. 2, 2019

Related U.S. Application Data
(60) Provisional application No. 62/720,677, filed on Aug. 21, 2018.
(60) Provisional application No. 62/714,030, filed on Aug. 2, 2018.

(51) Int. Cl. C23C 14/35; H05H 1/30; H05H 1/40

(52) U.S. Cl. CPC C23C 14/357; H05H 1/40; H05H 1/30

(57) ABSTRACT

Plasma spray systems comprise multiple zones wherein the energy required for different processes within the systems can be controlled independently. In some embodiments, a plasma spray system comprises a first zone wherein ionic species are generated from the target material using a first energy input, and the ionic species either combine to form a plurality of particles in the first zone, or form coatings on a plurality of input particles input into the first zone. The plasma spray system can further comprise a second zone, comprising a chamber coupled to a microwave energy source, which ionizes the plurality of particles to form a plurality of ionized particles and form a plasma jet. The plasma spray system can further comprise a third zone, comprising an electric field to accelerate the plurality of ionized particles and form a plasma spray.

### RELATED APPLICATIONS

This application claims the benefit of U.S. Provisional Patent Application No. 62/714,030, filed on Aug. 2, 2018, and entitled “Plasma Spray Deposition”; and U.S. Provisional Patent Application No. 62/720,677, filed on Aug. 21, 2018, and entitled “Plasma Spray Systems and Methods”; which are hereby incorporated by reference for all purposes.

### BACKGROUND

Plasma spraying processes—also referred to as thermal spraying—are used to deposit materials onto surfaces by introducing feedstock materials into a plasma jet output from a plasma torch. Thermal spraying can provide thick coatings (e.g., thicknesses range from 20 microns to several millimeters, depending on the process and feedstock), over a large area at high deposition rate as compared to other coating processes such as electroplating, physical and chemical vapor deposition. Feedstock materials available for thermal spraying include metals, alloys, ceramics, plastics and composites, and can be in the form of powders, liquids, suspensions, or in some cases wires. The feedstock material is heated by electrical (plasma or arc) or chemical means (combustion flame). Since the temperature in the plasma jet, to the extent that it may be possible to define a temperature, is typically approximately 5,000-8,000 K or more, the feedstock material may be heated, partially or fully melted or sublimated, or partially or fully evaporated, depending upon plasma pressure, nature of the feedstock material, including size of feedstock material or particles, and residence time of the feedstock material, as it is propelled towards a substrate by the plasma jet.

Upon encountering the substrate, in the case of fully or partially molten materials, the molten materials flatten and rapidly solidify forming a deposited layer of material on the substrate. Plasma spray deposited materials in this case therefore typically consist of a multitude of lamellae, formed by the flattening of the molten materials on the substrate. Conventional plasma spray processes typically produce coatings with large numbers of structural imperfections such as voids, cracks and delaminated regions between the lamellae. Consequently, plasma spray deposited layers tend to have significantly different properties from bulk materials with similar compositions, such as lower mechanical strength and elastic modulus, lower thermal conductivity, and lower electrical conductivity.

### SUMMARY

In some embodiments, a plasma spray system comprises a first zone comprising a target material and an apparatus having a power supply, wherein the power supply is configured to generate a plurality of ionic species from the target material using energy from the power supply; and the ionic species combine to form a plurality of particles. The plasma spray system can further comprise a second zone connected to an output of the first zone, the second zone comprising a chamber coupled to a microwave energy source. In the second zone, the microwave energy source can supply microwave energy to the chamber to ionize the plurality of particles to form a plurality of ionized particles, and a plasma jet comprising the plurality of ionized particles can be generated. The plasma spray system can further comprise a third zone connected to an output of the second zone, the third zone comprising an electric field, wherein the plurality of ionized particles can be accelerated by the electric field to form a plasma spray comprising the ionized particles.

In some embodiments, a plasma spray system comprises a first zone comprising an inlet wherein a plurality of input particles is input into the first zone, a target material and an apparatus having a power supply, wherein the power supply is configured to generate a plurality of ionic species from the target material using energy from the power supply, and the ionic species combine to form coatings on the plurality of input particles to form a plurality of coated particles. The plasma spray system can further comprise a second zone connected to an output of the first zone, the second zone comprising a chamber coupled to a microwave energy source. In the second zone, the microwave energy source can supply microwave energy to the chamber to ionize the plurality of coated particles to form a plurality of ionized particles, and a plasma jet comprising the plurality of ionized particles can be generated. The plasma spray system can further comprise a third zone connected to an output of the second zone, the third zone comprising an electric field, wherein the plurality of ionized particles can be accelerated by the electric field to form a plasma spray comprising the ionized particles.

In some embodiments, a method comprises providing a plasma spray system comprising: a first zone comprising a target material and an apparatus having a power supply; a second zone connected to an output of the first zone, the second zone comprising a chamber coupled to a microwave energy source; and a third zone connected to an output of the second zone, the third zone comprising an electric field. The method can further comprise generating a plurality of ionic species from the target material using energy from the power supply in the first zone; combining the ionic species to form a plurality of particles in the first zone; supplying microwave energy to the chamber using the microwave energy source to ionize the plurality of particles and form a plurality of ionized particles in the second zone; generating a plasma jet comprising the plurality of ionized particles in the second zone; and accelerating the plurality of ionized particles using the electric field in the third zone to form a plasma spray comprising the plurality of ionized particles.

In some embodiments, a method comprises providing a plasma spray system comprising: a first zone comprising an inlet wherein a plurality of input particles is input into the first zone, a target material and an apparatus having a power supply; a second zone connected to an output of the first zone, the second zone comprising a chamber coupled to a microwave energy source; and a third zone connected to an output of the second zone, the third zone comprising an electric field. The method can further comprise generating a plurality of ionic species from the target material using energy from the power supply in the first zone; combining the ionic species to form coatings on the plurality of input particles in the first zone to form a plurality of coated particles; supplying microwave energy to the chamber using the microwave energy source to ionize the plurality of coated particles and form a plurality of ionized particles in the second zone; generating a plasma jet comprising the plurality of ionized particles in the second zone; and accelerating the plurality of ionized particles using the electric field in the third zone to form a plasma spray comprising the plurality of ionized particles.

### BRIEF DESCRIPTION OF THE DRAWINGS

FIG. 1A is a schematic of stages in the present plasma spray deposition technology, in accordance with some embodiments.

FIG. 1B is an example of a plasma torch, in accordance with some embodiments, with an example simplified configuration having three zones.

FIG. 1C is an example of a plasma torch, in accordance with some embodiments, with an example simplified configuration having three zones.

FIG. 2 outlines a general high-level approach of the plasma torch of the present embodiments, which involves materials synthesis.

FIG. 3 shows an embodiment of one type of plasma-based coating technology—sputtering—in accordance with some embodiments, for coating particles of an input material with a sputtered coating material or for creating gas phase particles.

FIG. 4 shows a plasma torch with an example of ionization fraction enhancement, in accordance with some embodiments, for further ionization of the coated particles or species.

FIG. 5 shows an example of a plasma torch having multiple materials sputtering zones and magnetically enhanced plasma zones for improved plasma efficiency, in accordance with some embodiments.

FIG. 6 shows a plasma torch with an example of ionization materials acceleration, in accordance with some embodiments, for acceleration of charged ionized plasma-borne species of materials onto a biased or unbiased substrate.

FIG. 7 shows a plasma torch with examples of materials acceleration, in accordance with some embodiments.

FIG. 8 shows a simplified schematic of an example of a plasma spray system with multiple heads, which deposit streams of ionized particles onto a substrate, in accordance with some embodiments.

FIGS. 9 and 10 are flowcharts of methods utilizing plasma spray systems, in accordance with some embodiments.

### DETAILED DESCRIPTION

The present embodiments disclose plasma spray systems and methods, in which plasma jets containing single component or multi-component materials are generated. In some embodiments, materials from the plasma spray systems are collected as particles, while in other embodiments, the materials are deposited (or coated) onto substrates as films. The present plasma spray systems can be referred to as “plasma torches” and/or “plasma spray deposition systems” (when referring to systems capable of depositing films).

The materials within the present plasma jets can form high quality coatings on substrates, or can form unique particles that are collected. The formed particles and/or films can have novel properties, such as, but not limited to, atomic structures (e.g., particular carbon allotropes, or bonding characteristics between carbon and metals), morphologies (e.g., porosity, microstructures, and in some cases particle shapes), and/or other properties (e.g., surface area, purity, electrical conductivity, etc.)

Plasma spray systems are described that comprise multiple zones wherein the energy required for different processes within the systems can be controlled independently. In some embodiments, a plasma spray system comprises three zones. In these embodiments, the first zone creates or modifies particles, the second zone ionizes the particles and creates a plasma jet, and the third zone accelerates the ionized particles. The processes occurring in the three zones require different energy inputs, and the multiple zones of the present plasma spray systems enable the energy required for each process to be controlled independently. In some embodiments, the accelerated particles are then deposited as a film on a substrate. In some embodiments, modifying particles in the first zone comprises coating the particles with a coating material. In the present systems and methods, such coatings can completely cover particles, partially cover particles, or decorate particles. The produced coatings can also infiltrate into the particles (e.g., be deposited in pores within the input particles), in some embodiments.

In other embodiments, the particles that are output from the plasma spray system are collected, or are used as an input into a different downstream system. In some cases, plasma spray systems have a zone for particle collection in addition to two or three process zones, where the first process zone creates or modifies particles, the second process zone ionizes the particles and creates a plasma jet, an optional third process zone accelerates the ionized particles, and a collection zone condenses particles from the plasma jet and outputs the formed particles to a particle collection system. In some embodiments, particles (or coated particles) from a plasma spray system are collected, and subsequent downstream processing is performed. Some non-limiting examples of downstream processing include particle size reduction (e.g., by mechanical grinding), and/or methods that increase materials aggregate density (e.g., depositing a second material to fill voids) and its resulting electrical properties (e.g., to improve holistic electrical networked conductivity). An example of depositing a second material to fill voids is to deposit a carbon layer onto a porous carbon particle to increase the density of the carbon particles. In some embodiments, after downstream processing, the particles can be deposited on a substrate to form a coating (e.g., using wet coating methods, or a separate plasma spray coating system).

Further descriptions and examples of particle collection systems and methods that can be used in conjunction with the present plasma spray systems are described in U.S. Pat. No. 10,308,512, entitled “Microwave Reactor System with Gas-Solids Separation,” which is assigned to the same assignee as the present application, and is incorporated herein by reference as if fully set forth herein for all purposes.

The plasma spray systems and methods described herein are able to produce and/or process many different types of materials, including but not limited to metals, oxides, nitrides, carbon allotropes, charge storage materials, semiconductors, dielectrics, and magnetic materials. As such, the materials for the input particles, input gases and/or liquids, and the created particles and/or coatings in the first stage are not particularly limited. In some embodiments, the present plasma spray systems are capable of producing the wide variety of materials described herein with improved properties (e.g., with higher quality or other unique properties) compared to conventional systems, by leveraging the versatility of plasma processing (e.g., using microwave energy) and through the integration of multiple materials creation and/or coating zones (e.g., physical vapor deposition or sputtering zones) within the plasma spray system. Additionally, in some embodiments, further integration of an acceleration zone within the plasma spray system enables films with improved properties (e.g., lower porosity, and/or better adhesion) compared to conventional systems.

In some embodiments, input particles are input into a plasma spray system, and the input particles are coated and/or modified before forming an ionized plasma jet. In some embodiments, input particles are input into a plasma spray system and generated particles are generated in the plasma spray system, and the particles (both input and generated) are coated and/or modified before forming an ionized plasma jet.

Some examples of particles that can be created by and/or input particles that can be input into the present plasma spray systems are carbon allotropes, silicon, carbon, aluminum, ceramics (e.g., FeSi, SiOₓ). The produced or input particles are not particularly limited, and many different materials can be processed using the systems and methods described herein. In some non-limiting examples, materials with high permeability (e.g., nickel-iron soft ferromagnetic alloys), high relative permittivity (e.g., high-k dielectric materials such as perovskites), and/or high conductivity (e.g., metals) can be created and/or coated to produce materials or meta-materials for many different applications.

In some non-limiting examples, the generated and/or input particles that can be processed using the present systems and methods contain carbon allotropes, and are described in U.S. Pat. No. 9,997,334, entitled “Seedless Particles with Carbon Allotropes,” and in U.S. Pat. No. 9,862,606 entitled “Carbon Allotropes,” which are assigned to the same assignee as the present application, and are incorporated herein by reference as if fully set forth herein for all purposes. In some embodiments, the carbon particles that can be processed by the systems and methods described herein comprise a plurality of carbon aggregates, each carbon aggregate having a plurality of carbon nanoparticles, each carbon nanoparticle including graphene, with no seed (i.e., nucleation or core) particles. The graphene in the graphene-based carbon material can have up to 15 layers. A ratio, percentage or portion of carbon to other elements, except hydrogen, in the carbon aggregates can be greater than 99%, or greater than 99.5%, or greater than 99.7%, or greater than 99.9%, or greater than 99.95%. The aforementioned “other elements, except hydrogen” can include any element that is not carbon or hydrogen, such as, but not limited to, metals, halogens and/or oxygen. A median size of the carbon aggregates can be from 1 to 50 microns, or from 1 micron to 50 microns, or from 2 microns to 20 microns, or from 5 microns to 40 microns, or from 5 microns to 30 microns, or from 10 microns to 30 microns, or from 10 microns to 25 microns, or from 10 microns to 20 microns. In some embodiments, the size distribution of the carbon aggregates has a 10^{th} percentile from 1 micron to 10 microns, or from 1 micron to 5 microns, or from 2 microns to 6 microns, or from 2 microns to 5 microns. A surface area of the carbon aggregates can be at least 50 m²/g, or from 50 to 3000 m²/g, or from 100 to 3000 m²/g, or from 50 to 2000 m²/g, or from 50 to 1500 m²/g, or from 50 to 1000 m²/g, or from 50 to 500 m²/g, or from 50 to 300 m²/g, when measured using a Brunauer-Emmett-Teller (BET) method with nitrogen as the adsorbate. The carbon aggregates, when compressed, can have an electrical conductivity greater than 500 S/m , or greater than 1000 S/m, or greater than 2000 S/m, or from 500 S/m to 20,000 S/m, or from 500 S/m to 10,000 S/m, or from 500 S/m to 5000 S/m, or from 500 S/m to 4000 S/m, or from 500 S/m to 3000 S/m, or from 2000 S/m to 5000 S/m, or from 2000 S/m to 4000 S/m, or from 1000 S/m to 5000 S/m, or from 1000 S/m to 3000 S/m.

In some embodiments, particles are generated and/or input into the system, and these particles are modified (e.g., coated or decorated) in the first zone. Some examples of particles that can be generated and/or input into the system and modified in the first zone are carbon allotropes, silicon, carbon, aluminum, ceramics (e.g., FeSi, SiOₓ). Many different materials can be coated on the generated and/or input particles in the first zone, such as, but not limited to, carbon, sulfur, silicon, iron, nickel, manganese, metal oxides (e.g., ZnO, SiO, and NiO), metal carbides (e.g., SiC and AlC), metal silicides (e.g., FeSi), metal borides, metal nitrides (SiN), and many other types of ceramic materials.

In some embodiments, gases (or in some cases gases and/or liquids) are input into the system and particles are created and/or coated in the first zone from a target material and/or from the input gases (or in some cases the input gases and/or liquids). For example, gases and/or liquids that can be input into the system for carbon particle creation and/or coating input particles with carbon are methane, ethane, methylacetylene-propadiene propane (MAPP), hexane, and alcohols. In other non-limiting examples, generated particles and/or coatings on particles can be created and/or deposited from mixed materials such as trimethylamine (TMA), trimethylglycine (TMG), and methylacetylene-propadiene propane (TEOS). Some examples of particles that can be created from target materials in the first zone are phased carbons, silicon carbide, metal oxides, metal nitrides or metals. In some cases, input particles (i.e., input into the plasma spray system) are metals, and compound films (e.g., metal oxides or metal nitrides) are coated on the metallic input particles. In other cases, the input particles contain compound materials, and metallic coatings are deposited on the input particles. Some examples of particles that can be created from input gases (or in some cases the input gases and/or liquids) in the first zone are carbon allotropes (e.g., innate carbons), silicon, ZnO, AlOx, and NiO.

In some embodiments, the first zone in a plasma spray system comprises a target material and an apparatus having a power supply, wherein the power supply is configured to generate a plurality of ionic species from the target material and the ionic species combine to form a plurality of particles. The power supply can be an AC, DC, RF, or high-power impulse magnetron sputtering (HIPIMS) power supply and can be configured to generate a plurality of ionic species from the target material by tuning the power, voltage, frequency, repetition rate, and/or other characteristics of the power supply. The ionic species can be generated from the target material using the power supply via any process, such as one or more of physical vapor deposition (PVD), thermal evaporation, sputtering, and pulsed laser deposition.

In some embodiments, gases (or in some cases input gases and/or liquids) are input into the first zone in a plasma spray system to generate and/or coat particles and, additionally, the first zone comprises a target material and a power supply, as described above. In these embodiments, the ionic species generated from the target material can form additional particles in the first zone and/or coat the particles generated in the first zone from the input gases and/or liquids.

In some embodiments, a plurality of particles is input into the first zone, and the first zone comprises a target material and a power supply. In this case, a plurality of ionic species can be generated from the target material using the power supply and the ionic species can combine to form coatings on the plurality of input particles to form a plurality of coated particles. In this case, the ionic species can be generated from the target material using the power supply via any process, such as one or more of physical vapor deposition (PVD), thermal evaporation, sputtering, and pulsed laser deposition. As described above, many materials can be formed from these ionic species, including but not limited to, carbon, sulfur, silicon, iron, nickel, manganese, metal oxides (e.g., ZnO, SiO, and NiO), metal carbides (e.g., SiC and AlC), metal silicides (e.g., FeSi), metal borides, metal nitrides (SiN), and many other types of conductive and/or ceramic materials.

In other embodiments, the first zone creates particles or coats input particles using methods that do not require a target material, such as chemical vapor deposition (CVD), or plasma-enhanced chemical vapor deposition (PECVD). In such methods, the input gases are converted (e.g., dissociated) into the created particles within a reaction zone in the first zone, or into coatings on the input particles. As described above, many materials can be formed from these ionic species, including but not limited to, carbon, sulfur, silicon, iron, nickel, manganese, metal oxides (e.g., ZnO, SiO, and NiO), metal carbides (e.g., SiC and AlC), metal silicides (e.g., FeSi), metal borides, metal nitrides (SiN), and many other types of conductive and/or ceramic materials.

In some embodiments, the first zone contains more than one sub-zone. For example, particles can be input into the first zone, and the first zone contains more than one sub-zone to coat the input particles with more than one type of coating. In another example, in the first sub-zone of the first zone particles are created (e.g., from a target material), and the subsequent sub-zones coat the created particles with one or more layers of coatings.

In some embodiments, the second zone comprises a chamber coupled to a microwave energy source, wherein the microwave energy source supplies microwave energy to the chamber to ionize the plurality of particles (or coated particles) created and/or modified in the first zone to form a plurality of ionized particles. The microwave plasma is advantageous because the ionization efficiency of the particles (or coated particles) will be increased compared to other types of plasmas (e.g., those used in the first stage for materials creation). Although the fraction of ionized particles will be higher than that of the first stage, all of the particles will not necessarily be completely ionized in the second stage. A plasma jet comprising the plurality of ionized particles can also be generated in the second zone. The energetic ionized particles forming the plasma jet that is output from the second zone can be created solely using the microwave energy coupled to the chamber or can be created by adding additional energy (e.g., using additional electric or magnetic fields from electrodes or magnets) to the particles in the chamber. In some embodiments, a separate energy source will be used to add energy to the plasma jet (e.g., at a nozzle at the end of the second stage/zone) to include another stage of ionization prior to species discharge out of the second zone (or out of the torch).

In some embodiments, the microwave energy is coupled between the microwave energy source and the chamber in the second zone using a coaxial fed coupling, a coupling for the transverse electric (TE) mode of energy propagation, a coupling for the transverse magnetic (TM) mode of energy propagation, or a coupling for the transverse electromagnetic (TEM) mode of energy propagation.

In some embodiments, the microwave plasma in the second zone is produced using a microwave assisted filament method, with a coupling for the TEM mode of energy propagation.

The use of a microwave plasma to ionize particles in the second zone of the present plasma spray systems is beneficial compared to typical plasmas used in plasma torches (e.g., inductively coupled plasmas, capacitively-coupled plasmas, or plasmas formed using discharge plates). This is because microwave plasmas that have energies in the range of about 1 eV to about 20 eV are lower energy plasmas (i.e., “soft” plasmas) than are typical plasma torch plasmas that have energies from about 100 eV and higher. The lower energies of such soft plasmas enables particles to be effectively ionized (i.e., a high fraction of particles are sufficiently charged to be accelerated) without damaging and/or melting the particles. Since the particle morphologies are left intact, the utilization of a microwave plasma in the second zone enables plasma spray systems capable of creating particles and depositing films with unique morphologies. The use of microwaves to form the plasma also improves the power consumption efficiency of the system because energy can be coupled to the plasma more efficiently than in other types of plasmas. In some embodiments, greater than 90%, or greater than 95%, or greater than 98% of the microwave energy is coupled into the microwave plasma in the present plasma spray systems. Further description and examples of systems and methods for forming beneficial low energy microwave plasmas that can be used in conjunction with the present plasma spray systems are described in U.S. Pat. No. 9,812,295, entitled “Microwave Chemical Processing,” or in U.S. Pat. No. 9,767,992, entitled “Microwave Chemical Processing Reactor,” which are assigned to the same assignee as the present application, and are incorporated herein by reference as if fully set forth herein for all purposes.

In some embodiments of the present plasma spray systems, the first and second zones are connected such that the particles created, modified or coated in the first stage will be efficiently transferred into the second stage without needing to be collected between the zones. In some embodiments, a flowing carrier gas and/or applied electric fields (e.g., using externally biased plates) facilitates particle movement from the first to the second zone. In some embodiments, one or more couple regions are disposed between the first and second zone to facilitate transfer of particles from the first to the second zone.

In some embodiments, the first and second zones, along with any coupling regions between the zones, is shielded (e.g., with dielectric materials, or dielectric coatings) to reduce the amount of recombination of charged species. By preventing recombination, the shielding can improve output ionization efficiency (i.e., improve the fraction of ionized particles, or other species, output from the first zone). In some embodiments, magnetic shielding will be used to prevent recombination and provide higher output ionization efficiency.

In some embodiments of the present plasma spray systems, the third zone comprises an electric field, wherein the plurality of ionized particles are accelerated by the electric field to form a plasma spray comprising the ionized particles. In some embodiments, the accelerated particles are then deposited as a film on a substrate. For example, the electric field in the third zone can be created by applying a potential between a first (e.g., annular or porous) electrode and a porous electrode (e.g., a screen) or the substrate, such that the ionized particles are accelerated through the porous electrode onto the substrate to form a high-quality (e.g., dense) film.

In some embodiments, the pressure in all three zones of the plasma spray systems described herein is the same (or similar), while in other embodiments, the pressure in each zone can be different. In some embodiments, all zones are maintained at atmospheric pressure, at close to atmospheric pressure, or at low pressure. For example, the pressure in one, two, three, or all of the zones can be from 0.1 atm to 10 atm, or from 0.5 atm to 10 atm, or from 0.9 atm to 10 atm, or greater than 0.1 atm, or greater than 0.5 atm, or greater than 0.9 atm.

Several non-limiting example embodiments will now be described of the plasma spray systems and methods described above.

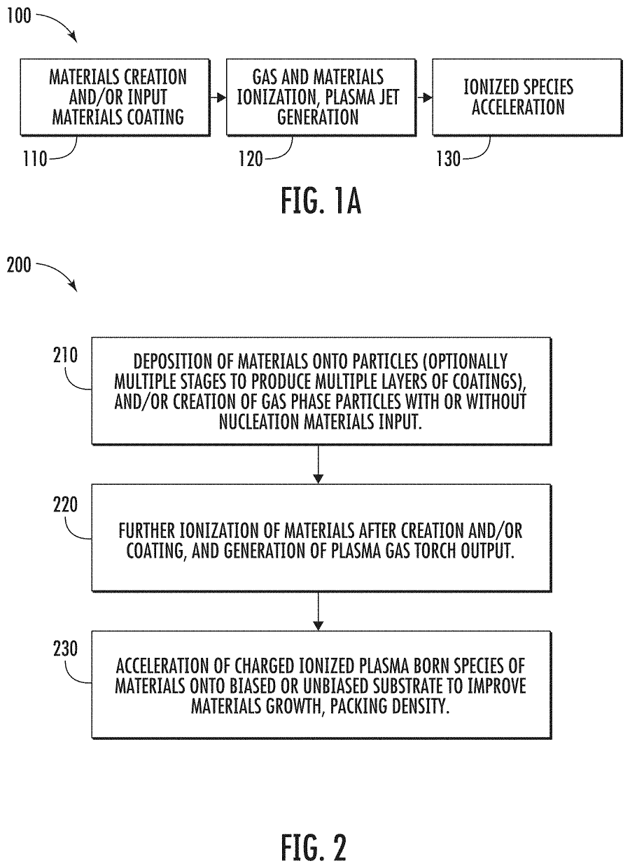

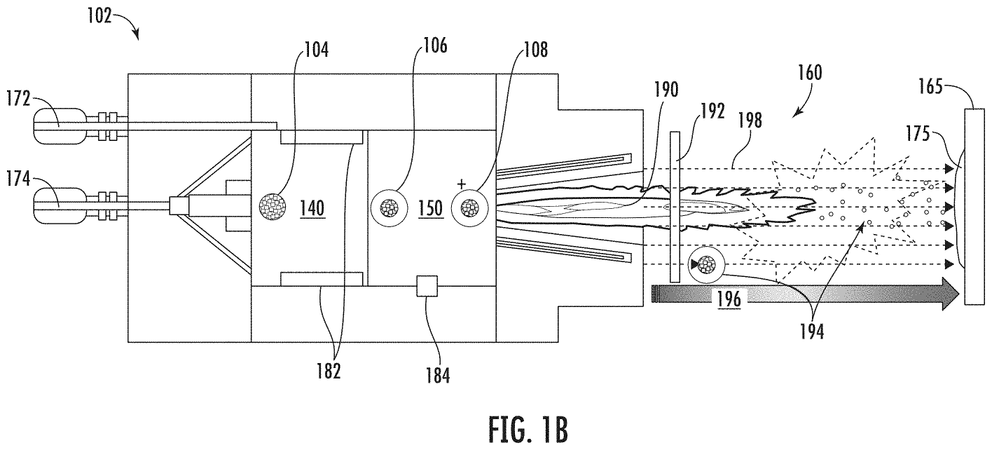

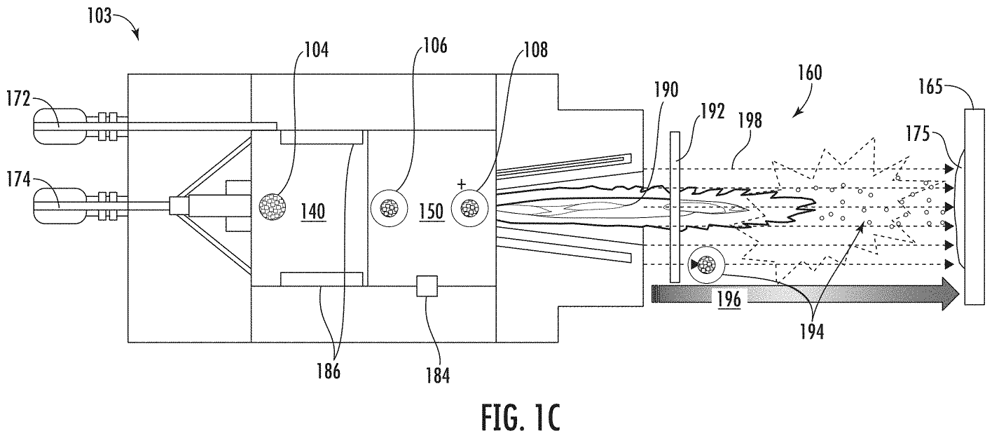

FIG. 1A is a flowchart of a method 100 to use a present plasma spray system 102, in accordance with some embodiments. In a first step 110 that occurs in a first zone of a plasma spray system (as described above), materials are created and/or input materials are coated with another substance, such as particles sputtered from a target material. A second step 120 that occurs in a second zone of a plasma spray system, involves gas and materials ionization, and plasma jet generation. In a third step 130 that occurs in a third zone of a plasma spray system, the ionized species are accelerated, giving the ionized materials high energy for coating the substrate.

FIG. 1B is simplified schematic example of a present plasma torch (i.e., plasma spray system) 102, in accordance with some embodiments, with configuration of three zones 140, 150 and 160 that perform the processes described in the three steps shown in FIG. 1A. The three zones shown in FIG. 1B correspond to the three zones described above in accordance with some embodiments. The first zone 140 is the coating and/or creation zone, the second zone 150 is the ionization zone, and the third zone 160 is the acceleration zone. Also shown in FIG. 1B are two inlets 172 and 174 for input materials—one inlet 172 for input gas and one inlet 174 for input particles , in accordance with some embodiments. The figure shows the input gas inlet 172 is coupled to the first zone 140. In some embodiments, the input gas inlet is coupled to the first zone 140, or the second zone 150, or there can be more than one input gas inlet coupled into the first and/or second zones. In some cases, the input particles will be input into inlet 174 as a colloidal dispersion of particles mixed with gases and/or liquids. In the example shown in FIG. 1B, the first zone 140 includes a target (i.e., target material) 182 from which the ionic species (not shown) are created, and these ionic species either form particles (not shown), or coat the input particles 104. The second zone 150 includes a microwave energy input 184, and a microwave plasma is formed in this zone from an input gas provided to the second zone 150 (e.g., from gas flowing through the first zone introduced to the system 102 from inlet 172 coupled to the first zone, or from an inlet (not shown) coupled directly into the second zone). The microwave plasma further ionizes particles or coated particles 106 that are output from the first zone 140. In some cases, the microwave plasma ionizes some of the atoms in the particles or coated particles 106 output from the first zone 140 to form ionized particles 108 (i.e., all of the atoms comprising the particles are not necessarily ionized in the second zone). The plasma jet 190 (i.e., torch flame) is output from the second zone 150. The plasma jet 190 that is output from the second zone 150 can be produced, confined and/or directed solely using the microwave energy in the second zone 150 or by adding additional energy (e.g., using additional electric or magnetic fields from electrodes and/or magnets). The third zone 160 in the figure includes a first porous electrode 192 (e.g., a screen that allows the ionized particles 108 and 194 to pass through), which accelerates the ionized particles 194 towards a substrate 165 via a potential gradient 196 (or a gradient of increasing energy), and a coating 175 (i.e., a film, or layer) is deposited on the substrate 165.

In some embodiments, the microwave (MW) energy is input directly into second zone (e.g., 150 in FIG. 1B), bypassing first zone (e.g., 140 in FIG. 1B). This can be accomplished, for instance, using a waveguide coupling the microwave energy source to the second zone. In other embodiments, the MW energy is input through first zone (e.g., 140 in FIG. 1B) into second zone (e.g., 150 in FIG. 1B). For example, MW can be input into the first zone and pass through the first zone (with or without interacting with the gases and/or particles in the first zone) and enter the second zone. This can be accomplished, for instance, using a waveguide that passes through the first zone (e.g., the chamber forming the first zone can itself form a portion of the waveguide) coupling the microwave energy source to the second zone. In some cases, the first zone can serve as a chamber for materials creation and as a waveguide to transmit the microwave energy from the microwave energy source to the second zone.

In some embodiments, a plasma spray system 103 is shown in FIG. 1C and utilizes CVD techniques to generate ionic species from an input material (e.g., an input gas) in the first zone. Plasma spray system 103 is similar to the system 102 shown in FIG. 1B, and contains many of the same components, except it does not have a target 182 in the first zone, and instead has energy input 186. Energy input 186 provides energy to the plasma spray system 103 to drive CVD reactions, instead of using PVD techniques, to generate ionic species from an input material (e.g., an input gas) in the first zone. The CVD generated ionic species can condense to form particles, or can coat input particles that have been input into the first zone. The energy input 186 is used to provide energy into the first zone to enable the CVD reactions to occur in the first zone. This energy input 186 can input any type of energy into the first zone that is capable of driving the CVD reactions. For example, the energy input 186 can be a microwave energy input (similar to microwave energy input 184 into the second zone), or it can be a thermal energy input (e.g., utilizing resistive heaters).

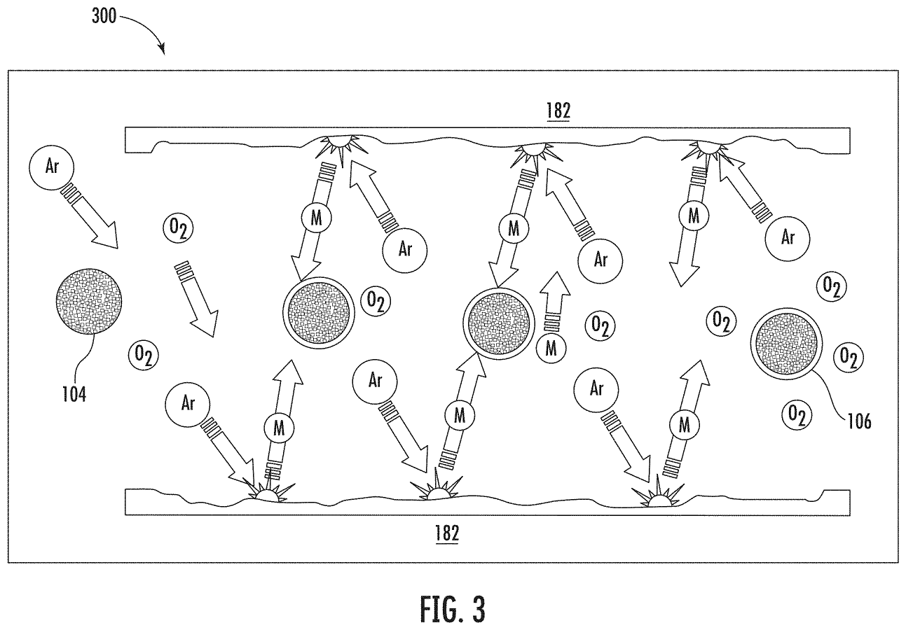

FIG. 2 is a flowchart of a method 200 for using the present plasma spray systems with more details of the three steps 110, 120 and 130 in method 100 (e.g., that occur in zones 140, 150 and 160 of the plasma torch 102 in FIG. 1B), in accordance with some embodiments. The first step 210 involves materials synthesis to coat input particulate materials or create particles, and can occur in a first zone of a plasma spray system (e.g., 140 in FIG. 1B). In step 210, materials are deposited onto particles and/or gas phase particles are created with or without nucleation materials input. In some embodiments, the first step 210 includes the deposition of materials onto particles in one or more sub-stages to create one or more coating layers. The first step 210 may also include the creation of particles from the gas phase with or without nucleation materials input. In some embodiments, PVD (e.g., using target materials) or CVD (e.g., thermal or plasma enhanced) methods are used to produce or coat the particles in the first step 210. The second step 220 includes ionization fraction enhancement (e.g., using microwave energy, or high-frequency RF energy), and can occur in a second zone of a plasma spray system (e.g., 150 in FIG. 1B). In the second step 220, the materials created and/or coated in the first step 210 are further ionized, and a plasma gas torch (i.e., a plasma jet) is generated as an output. The third step 230 includes accelerating the ionized materials produced in the second step 220, and can occur in a third zone of a plasma spray system (e.g., 160 in FIG. 1B). In the third step 220, the charged ionized plasma-borne species of materials (i.e., the plasma jet) are accelerated using an electric field (e.g., from a DC/AC, or high frequency RF potential) and impinge onto a biased or an unbiased substrate to form a film on the substrate. The acceleration in the third step 230 has the benefit of improving the quality of the film growth and/or the packing density of the film on the substrate. In some embodiments, the acceleration in the third step 230 enables the ionized materials to become embedded (i.e., subplanted) under the surface of the growing coating being deposited on the substrate, which improves the packing density (e.g., reduces the void volume) of the growing coating. In some embodiments, the acceleration in the third step 230 enables the ionized materials to become embedded under the surface of the substrate, providing anchoring for subsequent materials deposition and/or improved coating adhesion to the substrate.

An example of coated particles that can be produced by the systems and methods described herein (e.g., in FIGS. 1A and 2, respectively) are carbon particles coated with a low melting point metal (e.g., less than or equal to 1000° C., or less than or equal to 800° C., or less than or equal to 600° C.) such as aluminum. The carbon particles can be produced in zone 1 or input into zone 1 as input particles. Then in zone 2 the low melting point metal such as aluminum can be deposited onto the carbon particles using any of the PVD or CVD techniques described herein (e.g., sputtering from a metal target). Since the metal has a low melting point and carbon allotropes have high melting points (e.g., about 1500° C.), the metal can be coated onto the carbon particles at a temperature (e.g., approximately at, or slightly above, the melting point of the metal) that will not disturb or damage the carbon particle morphology. For example, the carbon particles can have a 3D mesoporous morphology that is beneficial to an end use application (e.g., a battery electrode), and the low melting point metal can be deposited on the carbon particle without changing the carbon particle morphology beneath the metal coating. In some embodiments, then the coated metal particles can be accelerated in a third zone and deposited as a dense film on a substrate, wherein the film contains carbon particles with the beneficial morphologies intact within a matrix of the low melting point metal.

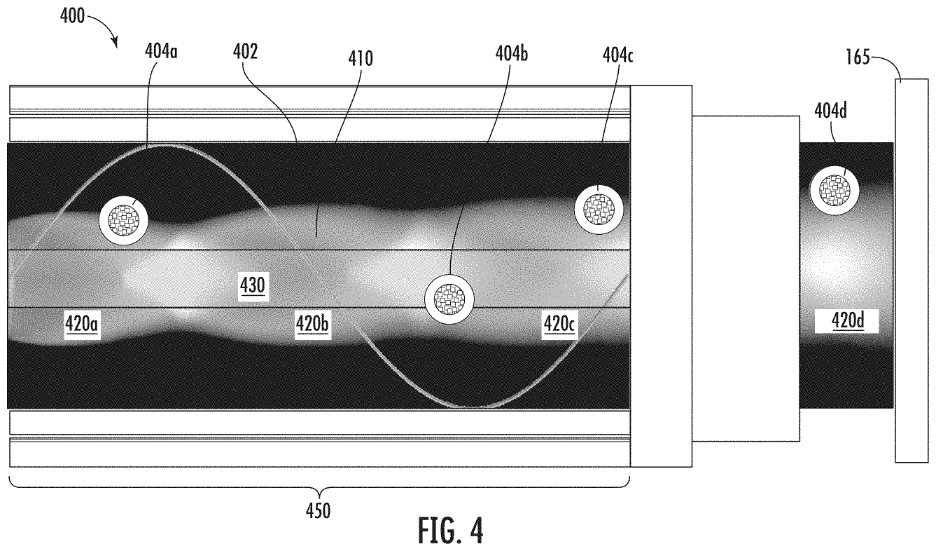

FIG. 3 shows a simplified schematic section 300 of an embodiment wherein a plasma-based coating technology for the first stage (e.g., zone 140 of FIG. 1B, and/or in a system capable of performing step 210 in method 200) is sputtering, in accordance with some embodiments. In this embodiment, a particulate input material 104 (e.g., a colloidal dispersion) is inserted into the system (e.g., system 102 in FIG. 1B) and the particulate input material 104 is coated with a sputtered coating material to produce coated particles 106 output from the first zone (e.g., 140 in FIG. 1B). In such systems an input gas shown as “Ar” in the figure generates ionic species shown as “M” in the figure from the target 182. The ionic species are deposited on the surfaces of the input particulate materials 104 to form coated particulate materials 106. In other embodiments (not shown in the figure), there are no input particulate materials and the ionic species “M” generated from the target(s) 182 combine to create particles from the gas phase. In some cases, reactive sputtering is used in this first step and/or zone depicted in FIG. 3, and the coatings and/or particles created can be compounds including the target material and another input gas shown as “O₂” in the figure. The use of “Ar” and “M” in the figure are non-limiting examples only, and other input gases (e.g., argon, nitrogen and oxygen) and ionized species (e.g., metals, semiconductors or insulators) can also be utilized in the present systems and methods. For example, sputtering is a versatile technique capable of producing many different elemental and compound materials, many of which are compatible with the present systems and methods in different embodiments. Some non-limiting examples of sputtered coatings and/or particles that can be created in the first step and/or zone of the plasma spray methods and systems described herein are carbon allotropes, sulfur, silicon, iron, nickel, and manganese, as well as elemental metals, metal alloys, metal oxides, and metal nitrides.

In the example first zone shown in FIG. 3, the target 182 can take any form factor, such as a disk, tube, wire, powder, or a coating on a surface. For example, the target 182 can be a tube that forms the walls of the chamber comprising the first zone 140. In some embodiments, the target 182 can be continuously or intermittently replenished while the system is running. For example, the target 182 can be a powder that is replenished using a particulate delivery system that feeds the particles to the first zone where they are totally or partially converted to ionic species. In another example, the target 182 can be a wire, or plurality of wires, that is replenished using a wire feedthrough apparatus.

In some embodiments, high-power impulse magnetron sputtering (HIPIMS) can be used to generate the ionic species from the target 182 and create or coat the particles 104 in the first stage (e.g., zone 140 in FIG. 1B). For example, a power supply in the first stage can be configured for HIPIMS and supply power densities from 1 to 100 kW-cm⁻² in pulses from 1 to 100 microseconds long, at a duty cycle from 1 to 25%. The advantage of using HIPIMS in the first stage is that the generated ionic species have a high degree of ionization and/or a high rate of molecular gas dissociation of the input gas (e.g., Ar), both of which result in produced particles or deposited coatings with high mass densities (e.g., with low porosity). In some embodiments, the average cathode power in a HIPIMS system is from 0.1 to 1000 W-cm⁻². In some embodiments, a power supply with a high voltage (e.g., about 3 kV, or from 1 to 10 kV) and a pulsed output (e.g., from 1 to 100 microseconds long, at a duty cycle from 1 to 25%) can be used in the first zone to create or coat materials. Such a power supply can be coupled to target 182 and produce ionic species from the target 182 in the first zone. In other cases, such a power supply can be used in CVD or PECVD systems in the first zone.

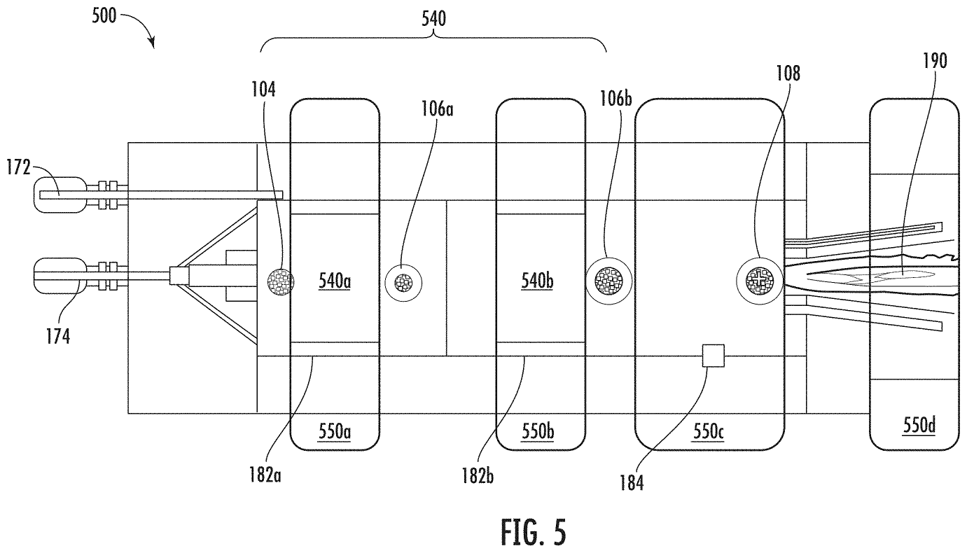

FIG. 4 shows a simplified schematic section 400 of a present plasma spray system with an example of ionization fraction enhancement in the second stage 450 (e.g., zone 150 of FIG. 1B, and/or in a system capable of performing step 220 in method 200), in accordance with some embodiments, for further ionization of the coated or generated particles from the first stage. The figure depicts microwave energy 410 within a chamber 402 in the second zone. Particles or coated particles 404a flow through the chamber and are modified by the microwave plasma such that the ionization density ρₑ of the particles is enhanced or increased as they flow through the chamber. This is shown in the figure as elements 420a-d, which increase in intensity from left to right in the figure. Likewise, particles 404a upon entering this second stage have a low ionization density ρₑ and particles 404b and 404c have increasingly higher ionization densities ρₑ as the particles move farther through the second stage. Particle 404d has a high ionization density and is output from the second stage (e.g., to be deposited on substrate 165). A surface wave plasma 430 of a transverse electromagnetic mode (TEM) of microwave energy propagation is also shown. In this form of wave propagation, current is flowing and being absorbed to the point where it creates a conductor capable of reaching a critical number density. This critical number density can then stop absorbing the microwave energy and can deliver the energy to other regions thereby propagating the energy within the chamber. As described previously, there are several different ways to couple the microwave energy into the chamber (e.g., coaxial fed, or utilizing TE, TM or TEM modes of energy propagation), and the present systems and methods can employ different coupling methods in different embodiments. Depending on the coupling method, the geometry of the chamber can be important. For example, the chamber itself can serve as a waveguide for the microwave energy, and the propagation direction can be parallel or perpendicular to the flow of particles through the second zone. In some embodiments, other features that are not shown in the example in FIG. 4 can be included in the microwave plasma region of the second zone, such as filaments, point sources, electrodes, and/or magnets to improve the plasma density and/or aid in the plasma ignition.

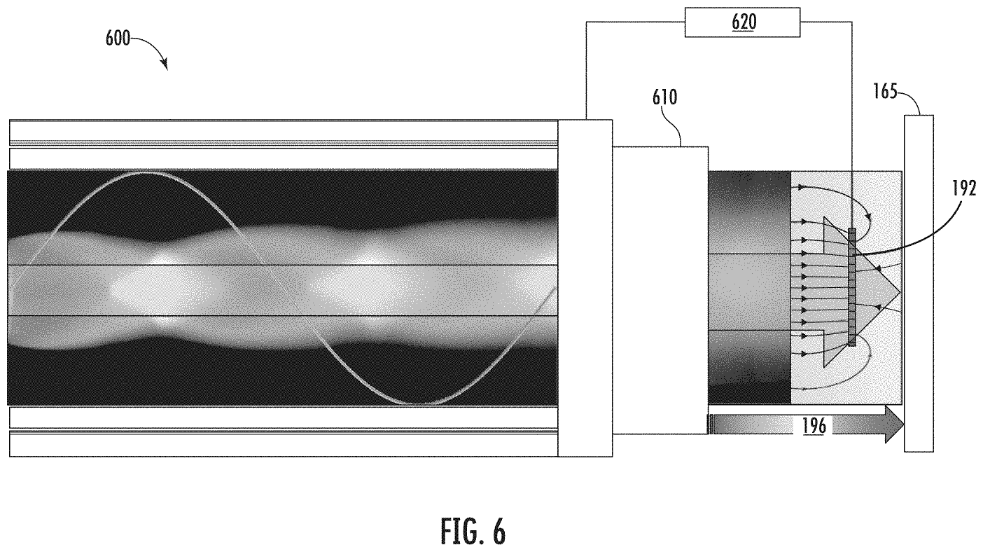

FIG. 5 shows an example of a plasma torch 500 having a first stage 540 with multiple materials sputtering sub-zones 540a and 540b. The multiple sub-zones 540a and 540b within the first zone 540 enable multiple coatings to be deposited on input particles, for particles to be created in the first sub-zone and then coated in the second sub-zone, and/or for different types of particles to be created in the first sub-zone and the second sub-zone. The non-limiting example shown in FIG. 5 includes particle 104 input into the first stage, which are coated in first sub-zone 540a of the first stage 540 using target 182a to form coated particles 106a, and subsequently the coated particles 106a are coated with a second coating layer in second sub-zone 540b of the first stage 540 using target 182b to form second coated particles 106b. For example, materials for Li-ion battery electrodes with multiple coating layers can be created in a system with multiple sub-zones within the first zone. In such an example, porous carbon particles 104 (e.g., containing ordered graphene phases) can be input into the first zone, and the surface area can be increased through the deposition of a coating of orthogonally grown carbon onto the input particles in a first sub-zone 540a. In a second sub-zone 540b, the coated particles 106a can be further coated with a solid electrolyte interphase (SEI) layer (e.g., silicon and/or sulfur) forming particles 106b. Such multiple layer coated particles can be used in batteries to enhance battery performance. It is advantageous to use such a multistage plasma torch to create multilayer battery materials to improve the battery performance as well as reduce the costs of manufacturing compared to methods that rely on sequential coating steps.

FIG. 5 also shows magnetically enhanced plasma zones for improved plasma efficiency, in accordance with some embodiments. In some embodiments, the deposition rate of the materials in the first zone (or sub-zones of the first zone) is improved using magnets 550a-d coupled to the first, second and/or third zones. In some cases, certain target materials require a high density of surface ions to achieve an appreciable deposition rate, and the addition of magnets 550a-b in zones with targets can increase the density of surface ions by confining the electrons (i.e., a “magnetic bottle” can be created using magnetic fields). The magnets can be either permanent magnets or electromagnets in different embodiments. FIG. 5 also illustrates that permanent or electromagnets 550c-d can be used to confine or direct the microwave plasma in the second zone to increase the plasma density and/or create or direct the particles in the plasma jet 190. In some cases, the external magnets (permanent or electromagnets) are used to increase the ionization efficiency in the first and/or second zones.

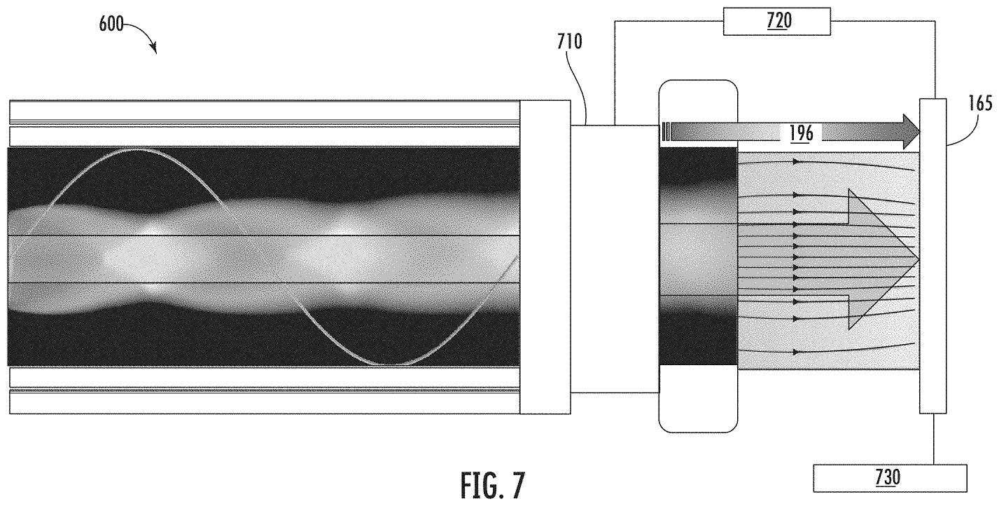

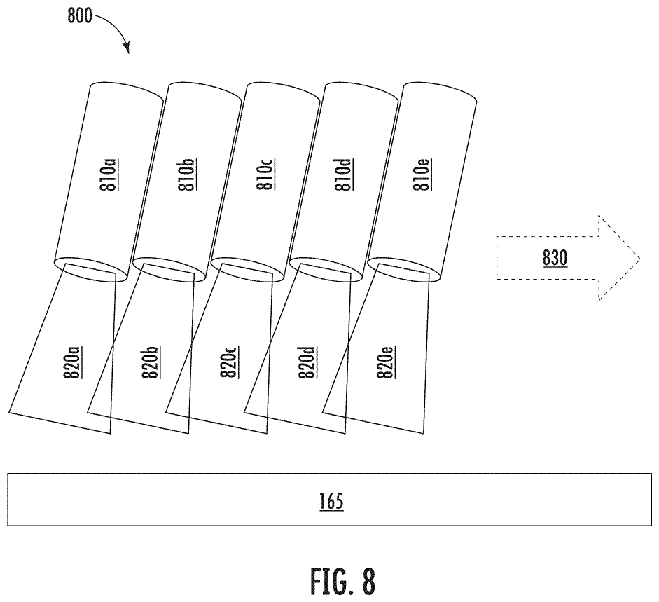

FIGS. 6 and 7 show plasma torches 600 and 700 with examples of different configurations of systems for ionized materials acceleration, in accordance with some embodiments. The plasma torches are similar to plasma torches 102, 400 and 500, and contain similar components, however all of the components are not labeled in FIGS. 6 and 7. The acceleration of the charged ionized plasma-borne species of materials (i.e., the plasma jet output from the second stage) is advantageous to form high quality films on biased or unbiased substrates.

FIG. 6 shows a plasma torch 600 with a similar configuration to that shown in plasma torch 102 in FIG. 1B, and includes a porous electrode 192 (e.g., a screen that allows the ionized particles to pass through), which accelerates ionized particles towards substrate 165 via a potential gradient 196 (or a gradient of increasing energy), to form a coating (i.e., a film, or layer) on the substrate 165. In this configuration a potential is applied between a first electrode 610 at or near the outlet of the second zone of the plasma torch 600 and the porous electrode 192 using a power supply 620. The power supply 620 can be a high-voltage power supply that applies a large potential between the electrode 610 and the porous electrode 192. The first electrode 610 can be a physical electrode (e.g., a porous or an annular electrode that allows the ionized particles to pass through), or the plasma in the second zone can function as the first electrode 610. The applied potential in this example can be a DC, a pulsed-DC, or an AC voltage. The applied voltage can be any voltage (e.g., from 25 V to 10 kV), and is typically dependent on the application.

FIG. 7 shows a plasma torch 700 with two different examples of system configurations for ionized materials acceleration, in accordance with some embodiments. In a first example a high-voltage power supply 720 applies a potential between an electrode 710 (e.g., a porous or annular electrode that allows the ionized particles to pass through) and the substrate 165. In a second example, the electrode 710 is grounded, and an RF power supply 730 is used to bias the substrate 165 to generate the electric field that accelerates the plasma jet onto the substrate. The applied high-voltage in either of these examples can be a DC, a pulsed-DC, or an AC voltage.

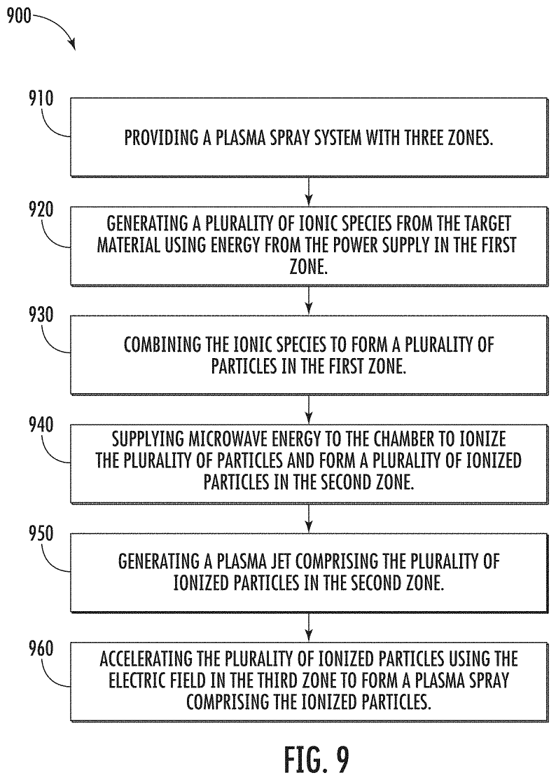

In some embodiments, the output of the plasma spray systems described herein are directed to a substrate to form coatings on the substrate. In some embodiments, a single head outputs the stream of ionized particles onto the substrate. In other embodiments, multiple heads are configured in parallel to output multiple streams of ionized particles onto the substrate. In other embodiments, a single head or multiple heads output one or more streams of ionized particles onto the substrate, and the one or more heads are scanned across the substrate to increase the coverage across the substrate. FIG. 8 shows a simplified schematic of an example of a plasma spray system 800 with multiple heads 810a-e, which deposit streams of ionized particles 820a-e onto a substrate 165. In some embodiments, each head 810a-e is similar to the systems shown in FIG. 1B, and/or in any of FIGS. 3-7. FIG. 8 also shows that, optionally, the plasma spray system 800 with multiple heads 810a-e can be scanned in a direction 830 across the substrate 165 to increase the coverage.

In some plasma spray embodiments, the third stage can be omitted. In such cases, the plasma jet that is output from the second stage can be directed to a substrate to form a coating without the high acceleration provided by the third stage.

In some plasma spray embodiments, the second stage can be omitted. In such cases, the created, modified or coated particles that are output from the first stage can be fed directly to the third stage to be accelerated, and in some cases be directed to a substrate to form a coating.

In some embodiments, the output of a reactor for generating particulate materials can be connected to the input of the first stage of the present plasma spray systems. For example, a microwave plasma reactor can be used to generate particulate materials, and the particles output from the reactor are input into first stage (i.e., without collecting the particles between the reactor and the plasma spray system). In some embodiments, a thermal plume and/or afterglow output from the reactor can also be input into the first stage of a present plasma spray systems along with produced particulate materials. Some examples of microwave plasma reactors that can be coupled to the input of the present plasma spray systems are described in the aforementioned U.S. Pat. No. 9,812,295, or U.S. Pat. No. 9,767,992, which are incorporated herein by reference as if fully set forth herein for all purposes. In another example, a thermal cracking reactor can be used to generate particulate materials, and the particles output from the reactor are input into first stage of the present plasma spray systems. Some examples of thermal reactors that can be coupled to the input of the present plasma spray systems are described in U.S. Pat. No. 9,862,602, entitled “Cracking of a Process Gas,” which is assigned to the same assignee as the present application, and is incorporated herein by reference as if fully set forth herein for all purposes.

There are many applications for particles and coatings produced using the plasma spray systems and methods described herein, including different types of mechanical, electrical, and optical applications. For example, the present plasma sprayed coatings can be applied to improve the mechanical properties of structural materials, to create thermal barrier coatings, or to prevent corrosion, erosion, or wear of a surface or an object. The present plasma sprayed coatings can also be used to alter the optical, electrical, magnetic, or tribological properties of a surface or object.

One example application for the present plasma sprayed coatings are electrodes in high capacity lithium ion batteries. For example, carbon-based particulate particles can be input into the system with high surface area to volume ratios, and/or with beneficial morphologies for charge extraction during battery operation. The input particles can then be coated with one or more active battery electrode materials (e.g., sulfur or silicon) in the first stage (e.g., using sputtering). The coated particles can then be further ionized in the second stage, accelerated in the third stage, and deposited onto a conductive substrate to form a dense high quality film for a battery electrode.

In some embodiments, a plasma spray method (e.g., similar to method 100 in FIG. 1A, in some embodiments), comprises generating a plurality of ionic species from a target material to form a plurality of particles, ionizing the plurality of particles to form a plurality of ionized particles and generating a plasma jet comprising the plurality of ionized particles, and accelerating the plurality of ionized particles to form a plasma spray comprising the ionized particles. In some embodiments, the plurality of accelerated ionized particles is then directed to a substrate and form a coating on the substrate.

In some embodiments, a plasma spray method (e.g., similar to method 100 in FIG. 1A, in some embodiments) comprises supplying a plurality of input particles and generating a plurality of ionic species from a target material, wherein the ionic species form coatings on the input particles, to form a plurality of coated particles. The plurality of coated particles is then ionized to form a plurality of ionized particles and a plasma jet comprising the plurality of ionized particles is generated. The plurality of ionized particles is then accelerated to form a plasma spray comprising the ionized particles in a third stage. In some embodiments, the plurality of accelerated ionized particles is then directed to a substrate and form a coating on the substrate.

Depending upon conditions in the present plasma torches, the plasma (e.g., in the second zone) may be a thermal plasma in which the various degrees of freedom approach thermal equilibrium, or a cold plasma, in which, for example, the translational degrees of freedom of the molecules, atoms and ions are only excited to an equivalent temperature that is much cooler than the higher temperature corresponding to the energy in the degrees of freedom corresponding to ionization and/or excitation of atomic and molecular species. Parameters for forming thermal and cool plasmas that may be used to tailor the creation of the materials described herein include controlling for plasma pressure, current duration and duty cycle, pulsation of the power source, and the presence or absence of species that have, for example, high or low electron capture cross-section. These plasma formation parameters can be tuned based on, for example, the types of input materials and the particle sizes that are being processed.

Methods of optimizing the plasma spraying process may include tailoring plasma spray parameters such as, but not limited to: design features encouraging or discouraging increased residence time of particles (e.g., in the first and/or second zones), control for pressure of plasma such as at atmospheric pressure or at substantially lower pressure (e.g., in the second zone), tuning various continuous or pulsed power sources including wave-sourced power (e.g., for the plasma in the second zone) such as microwave power, or other sources of power (e.g., for the target material in the first zone) such as DC power or inductively-coupled or capacitively-coupled RF power, and physical-chemical aspects such as the addition of electropositive or electronegative species such as to alter the surface chemistry of the particles (e.g., in the first and/or second zones). Plasma spray parameters may also be customized to produce high-speed gas flow in order to dynamically embed produced particles into the substrate.

Thermal plasma may be particularly effective at promoting melt of particles (e.g., in the second zone), whereas cold plasma may be more effective at altering surface physical and chemical properties without fully melting the particles.

The plasma torch may include, in addition to a plasma generated, a high voltage DC or high-voltage low-frequency AC bias between the torch and the substrate upon which material is being deposited, such that either a substantial electric potential exists between torch body and substrate, and/or that a substantial electric current flows between torch and substrate. The voltage difference between the torch and substrate may be more than 100 kV, or more than 30 kV, or more than 10 kV, or more than 3 kV. The current between the torch and substrate may be more than 100 Amp, or more than 10 Amp, or more than 1 Amp.

The aforementioned voltage between torch and substrate and/or a coating of formed material will help accelerate particles toward the substrate to tailor the degree of embedding of particles in the matrix of the substrate. In some embodiments, for example, given a yield strength on the order of 100 MPa for the substrate, and given a charge on the particles of order 10,000 e (where e is the fundamental charge), and given a particle size of order 1 micron, a voltage gain of approximately 30 kV will help embed particles in the matrix of the substrate. Equivalent energies may be attained by a gas-dynamic co-flow in the plasma that accelerates the particles to speeds of 100 m/s or several times greater than 100 m/s (e.g., from 100 m/s to 1000 m/s).

In some embodiments, the aforementioned high current between torch and substrate and/or coating will enhance the formation of bonds of mixed covalent-metallic character between carbon and metal. For example, carbon particles can be input into the first zone and coated in metal from a target material in the first zone, and a dense film containing bonds of mixed covalent-metallic character between the carbon and the metal can be formed by accelerating the produced composite particles onto a substrate.

In some embodiments, film or coating deposition conditions can be tuned to customize the density of the formed bulk or film material. For example, particles synthesized through the torch can be ionized and heated within the second zone of the torch through ion bombardment by tuning the plasma power supply power to current flow. This tuning of conditions in the torch can tailor the compositionally combined material in a range of states—such as liquid to semi-solid states—so that the density of the deposited materials is controlled from fully densified to that of a more porous nature. Additionally, the output accelerator field in the third zone can be set to various voltages to implant materials, such as using low voltage levels to lightly connect the formed material to the substrate's surface.

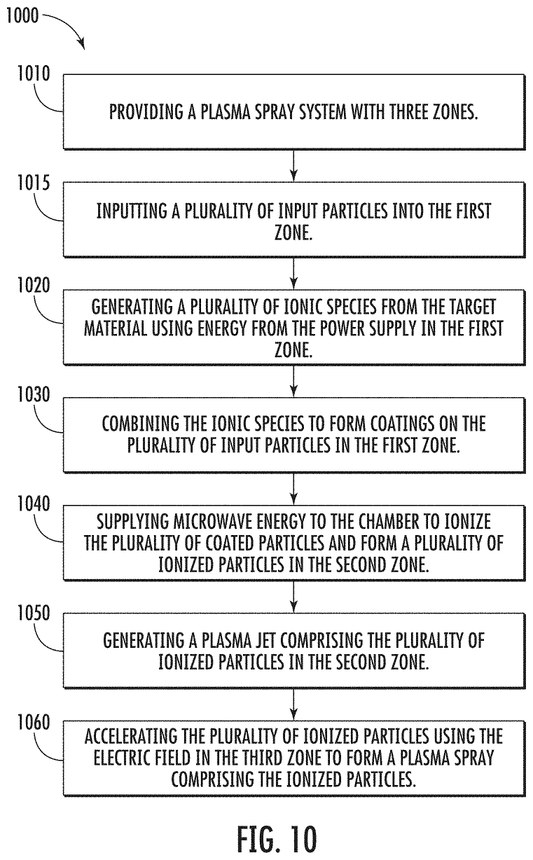

FIG. 9 is a flowchart of a method 900 utilizing a plasma spray system, in accordance with some embodiments. In step 910, a plasma spray system is provided comprising three zones. The first zone comprises a target material and an apparatus having a power supply, the second zone is connected to an output of the first zone and comprises a chamber coupled to a microwave energy source, and the third zone is connected to an output of the second zone and comprises an electric field. In step 920 a plurality of ionic species is generated from the target material using energy from the power supply in the first zone. In step 930, the ionic species are combined to form a plurality of particles in the first zone. In step 940, microwave energy is supplied to the chamber using the microwave energy source to ionize the plurality of particles and form a plurality of ionized particles in the second zone. In step 950, a plasma jet is generated comprising the plurality of ionized particles in the second zone. In step 960, the plurality of ionized particles are accelerated using the electric field in the third zone to form a plasma spray comprising the ionized particles.

FIG. 10 is a flowchart of a method 1000 utilizing a plasma spray system, in accordance with some embodiments. In step 1010, a plasma spray system is provided comprising three zones. The first zone comprises a target material and an apparatus having a power supply, the second zone is connected to an output of the first zone and comprises a chamber coupled to a microwave energy source, and the third zone is connected to an output of the second zone and comprises an electric field. In step 1015 a plurality of input particles is input into the first zone. In step 1020 a plurality of ionic species is generated from the target material using energy from the power supply in the first zone. In step 1030, the ionic species are combined to form coatings on the plurality of input particles in the first zone. In step 1040, microwave energy is supplied to the chamber using the microwave energy source to ionize the plurality of coated particles and form a plurality of ionized particles in the second zone. In step 1050, a plasma jet is generated comprising the plurality of ionized particles in the second zone. In step 1060, the plurality of ionized particles are accelerated using the electric field in the third zone to form a plasma spray comprising the ionized particles.

In method 900 or 1000, the ionic species can be generated from the target material using energy from the power supply by one or more processes of physical vapor deposition, thermal evaporation, sputtering, and pulsed laser deposition.

Method 900 or 1000, can further comprise a step wherein the plurality of ionized particles are accelerated by the electric field to form a coating on a substrate.

In some embodiments, a plasma spray system comprises: an inlet wherein one or more input gases are input into the system; a first zone comprising a reaction zone, wherein: the one or more input gases are input through the inlet into the first zone; the reaction zone is configured to generate a plurality of ionic species from the input gases; and the ionic species combine to form a plurality of particles; a second zone connected to an outlet of the first zone, the second zone comprising a chamber coupled to a microwave energy source, wherein: the microwave energy source supplies microwave energy to the chamber to ionize the plurality of particles to form a plurality of ionized particles; and a plasma jet comprising the plurality of ionized particles is generated; and a third zone connected to an outlet of the second zone, the third zone comprising an electric field, wherein the plurality of ionized particles is accelerated by the electric field to form a plasma spray comprising the ionized particles.

In some embodiments of the plasma spray system above, the plurality of particles are generated from the input gases by one or more processes of chemical vapor deposition, and plasma enhanced chemical vapor deposition.

In some embodiments of the plasma spray system above, the plurality of particles comprise materials selected from the group consisting of carbon allotropes, ZnO, SiO, SiC, AlC, FeSi, and NiO.

In some embodiments of the plasma spray system above, the plurality of ionized particles is accelerated by the electric field to form a coating on a substrate.

In some embodiments, a plasma spray system comprises: a first inlet wherein a plurality of input particles is input into the system; a second inlet wherein one or more input gases are input into the system; a first zone comprising a reaction zone, wherein: the plurality of input particles are input through the first inlet into the first zone; the one or more input gases are input through the second inlet into the first zone; the reaction zone is configured to generate a plurality of ionic species from the input gases; and the ionic species combine to form coatings on the plurality of input particles to form a plurality of coated particles; a second zone connected to an outlet of the first zone, the second zone comprising a chamber coupled to a microwave energy source, wherein: the microwave energy source supplies microwave energy to the chamber to ionize the plurality of coated particles to form a plurality of ionized particles; and a plasma jet comprising the plurality of ionized particles is generated; and a third zone connected to an outlet of the second zone, the third zone comprising an electric field, wherein the plurality of ionized particles are accelerated by the electric field to form a plasma spray comprising the ionized particles.

In some embodiments of the plasma spray system above, the plurality of input particles comprises carbon allotropes, silicon, carbon, aluminum, ceramics, FeSi, SiOx, materials with high permeability, nickel-iron soft ferromagnetic alloys, materials with high relative permittivity, high-k dielectric materials, perovskites, high conductivity materials, or metals.

In some embodiments of the plasma spray system above, the plurality of particles is generated from the input gases by one or more processes of chemical vapor deposition, and plasma enhanced chemical vapor deposition.

In some embodiments of the plasma spray system above, the coatings on the plurality of input particles comprise materials selected from the group consisting of carbon, sulfur, silicon, iron, nickel, manganese, metal oxides, ZnO, SiO, NiO, metal carbides, SiC, AlC), metal silicides FeSi, metal borides, metal nitrides, SiN, and ceramic materials.

In some embodiments of the plasma spray system above, the plurality of ionized particles is accelerated by the electric field to form a coating on a substrate.

In some embodiments, a method comprises: generating a plurality of ionic species from a target material to form a plurality of particles; ionizing the plurality of particles to form a plurality of ionized particles and generating a plasma jet comprising the plurality of ionized particles; and accelerating the plurality of ionized particles to form a plasma spray comprising the ionized particles.

In some embodiments of the method above, the plurality of ionic species is generated from the target material by one or more processes of physical vapor deposition, thermal evaporation, sputtering, and pulsed laser deposition.

In some embodiments of the method above, the plurality of particles comprise materials selected from the group consisting of carbon allotropes, ZnO, SiO, SiC, AlC, FeSi, and NiO.

In some embodiments of the method above, the plurality of particles is ionized using a microwave plasma.

In some embodiments the method above further comprises directing the plurality of ionized particles toward a substrate and forming a coating on a substrate.

In some embodiments, a method comprises: supplying a plurality of input particles; generating a plurality of ionic species from a target material, wherein the ionic species form coatings on the input particles, to form a plurality of coated particles; ionizing the plurality of coated particles to form a plurality of ionized particles and generating a plasma jet comprising the plurality of ionized particles; and accelerating the plurality of ionized particles to form a plasma spray comprising the ionized particles.

In some embodiments of the method above, the plurality of input particles comprises carbon allotropes, silicon, carbon, aluminum, ceramics, FeSi, SiOx, materials with high permeability, nickel-iron soft ferromagnetic alloys, materials with high relative permittivity, high-k dielectric materials, perovskites, high conductivity materials, or metals.

In some embodiments of the method above, the ionic species are generated from the target material by one or more processes of physical vapor deposition, thermal evaporation, sputtering, and pulsed laser deposition.

In some embodiments of the method above, the coatings on the plurality of input particles comprise materials selected from the group consisting of carbon, sulfur, silicon, iron, nickel, manganese, metal oxides, ZnO, SiO, NiO, metal carbides, SiC, AlC), metal silicides FeSi, metal borides, metal nitrides, SiN, and ceramic materials.

In some embodiments of the method above, the plurality of coated particles is ionized using a microwave plasma.

In some embodiments the method above further comprises directing the plurality of ionized particles toward a substrate and forming a coating on a substrate.

Reference has been made to embodiments of the disclosed invention. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

What is claimed is:

1. A plasma spray system, comprising:
a first zone comprising a target material and an apparatus having a power supply, wherein:
the power supply is configured to generate a plurality of ionic species from the target material using energy from the power supply; and
the ionic species combine to form a plurality of particles;
a second zone connected to an output of the first zone, the second zone comprising a chamber coupled to a microwave energy source, wherein:
the microwave energy source supplies microwave energy to the chamber to ionize the plurality of particles to form a plurality of ionized particles; and
a plasma jet comprising the plurality of ionized particles is generated; and
a third zone connected to an output of the second zone, the third zone comprising an electric field, wherein the plurality of ionized particles is accelerated by the electric field to form a plasma spray comprising the ionized particles.

2. The plasma spray system of claim 1, wherein the ionic species are generated from the target material using the energy from the power supply by one or more processes of physical vapor deposition, thermal evaporation, sputtering, and pulsed laser deposition.

3. The plasma spray system of claim 1, wherein the plurality of particles comprises materials selected from the group consisting of carbon allotropes, ZnO, SiO, SiC, AlC, FeSi, and NiO.

4. The plasma spray system of claim 1, wherein the plurality of ionized particles is accelerated by the electric field to form a coating on a substrate.

5. The plasma spray system of claim 4, further comprising a high-voltage power supply connected to a first electrode in the third zone and a porous electrode located between the third zone and the substrate to generate the electric field in the third zone and accelerate the ionized particles.

6. The plasma spray system of claim 4, further comprising a high-voltage power supply connected to a first electrode in the third zone and the substrate to generate the electric field in the third zone and accelerate the ionized particles.

7. The plasma spray system of claim 4, further comprising a high-voltage power supply connected to the substrate to generate the electric field in the third zone and accelerate the ionized particles.

8. The plasma spray system of claim 1, further comprising external magnets coupled to the first, second or third zones, wherein the magnets are permanent magnets or electromagnets.

9. A plasma spray system, comprising:
a first zone comprising an inlet wherein a plurality of input particles is input into the first zone, a target material and an apparatus having a power supply, wherein:
the power supply is configured to generate a plurality of ionic species from the target material using energy from the power supply; and
the ionic species combine to form coatings on the plurality of input particles to form a plurality of coated particles;
a second zone connected to an output of the first zone, the second zone comprising a chamber coupled to a microwave energy source, wherein:
the microwave energy source supplies microwave energy to the chamber to ionize the plurality of coated particles to form a plurality of ionized particles; and
a plasma jet comprising the plurality of ionized particles is generated; and
a third zone connected to an output of the second zone, the third zone comprising an electric field, wherein the plurality of ionized particles is accelerated by the electric field to form a plasma spray comprising the ionized particles.

10. The plasma spray system of claim 9, wherein the plurality of input particles comprises materials selected from the group consisting of carbon allotropes, silicon, carbon, aluminum, ceramics, FeSi, SiO,, materials with high permeability, nickel-iron soft ferromagnetic alloys, materials with high relative permittivity, high-k dielectric materials, perovskites, and high conductivity materials, metals.

11. The plasma spray system of claim 9, wherein the plurality of ionic species is generated from the target material using the energy from the power supply by one or more processes of physical vapor deposition, thermal evaporation, sputtering, and pulsed laser deposition.

12. The plasma spray system of claim 9, wherein the coatings on the plurality of input particles comprise materials selected from the group consisting of carbon, sulfur, silicon, iron, nickel, manganese, metal oxides, ZnO, SiO, and NiO, metal carbides, SiC and AlC, metal silicides, FeSi, metal borides, metal nitrides, SiN, and ceramics.

13. The plasma spray system of claim 9, wherein the plurality of ionized particles is accelerated by the electric field to form a coating on a substrate.

14. The plasma spray system of claim 13, further comprising a high-voltage power supply connected to a first electrode in the third zone and a porous electrode located between the third zone and the substrate to generate the electric field in the third zone and accelerate the ionized particles.

15. The plasma spray system of claim 13, further comprising a high-voltage power supply connected to a first electrode in the third zone and the substrate to generate the electric field in the third zone and accelerate the ionized particles.

16. The plasma spray system of claim 13, further comprising a high-voltage power supply connected to the substrate to generate the electric field in the third zone and accelerate the ionized particles.

17. The plasma spray system of claim 9, further comprising external magnets coupled to the first, second or third zones, wherein the magnets are permanent magnets or electromagnets.

18. A method, comprising:
providing a plasma spray system comprising:
a first zone comprising a target material and an apparatus having a power supply;
a second zone connected to an output of the first zone, the second zone comprising a chamber coupled to a microwave energy source; and
a third zone connected to an output of the second zone, the third zone comprising an electric field;
generating a plurality of ionic species from the target material using energy from the power supply in the first zone;
combining the ionic species to form a plurality of particles in the first zone;
supplying microwave energy to the chamber using the microwave energy source to ionize the plurality of particles and form a plurality of ionized particles in the second zone;
generating a plasma jet comprising the plurality of ionized particles in the second zone; and
accelerating the plurality of ionized particles using the electric field in the third zone to form a plasma spray comprising the plurality of ionized particles.

19. The method of claim 18, wherein the ionic species are generated from the target material using energy from the power supply by one or more processes of physical vapor deposition, thermal evaporation, sputtering, and pulsed laser deposition.

20. The method of claim 18, wherein the plurality of particles comprises materials selected from the group consisting of carbon allotropes, ZnO, SiO, SiC, AlC, FeSi, and NiO.

21. The method of claim 18, wherein the plurality of ionized particles is accelerated by the electric field to form a coating on a substrate.

22. A method, comprising:
providing a plasma spray system comprising:
a first zone comprising an inlet wherein a plurality of input particles is input into the first zone, a target material and an apparatus having a power supply;
a second zone connected to an output of the first zone, the second zone comprising a chamber coupled to a microwave energy source; and
a third zone connected to an output of the second zone, the third zone comprising an electric field;
generating a plurality of ionic species from the target material using energy from the power supply in the first zone;
combining the ionic species to form coatings on the plurality of input particles in the first zone to form a plurality of coated particles;
supplying microwave energy to the chamber using the microwave energy source to ionize the plurality of coated particles and form a plurality of ionized particles in the second zone;
generating a plasma jet comprising the plurality of ionized particles in the second zone; and
accelerating the plurality of ionized particles using the electric field in the third zone to form a plasma spray comprising the plurality of ionized particles.

23. The method of claim 22, wherein the ionic species are generated from the target material using energy from the power supply by one or more processes of physical vapor deposition, thermal evaporation, sputtering, and pulsed laser deposition.

24. The method of claim 22, wherein the coatings on the plurality of input particles comprise materials selected from the group consisting of carbon allotropes, ZnO, SiO, SiC, AlC, FeSi, and NiO.

25. The method of claim 22, wherein the plurality of input particles comprises materials selected from the group consisting of carbon allotropes, silicon, carbon, aluminum, ceramics, FeSi, SiO,, materials with high permeability, nickel-iron soft ferromagnetic alloys, materials with high relative permittivity, high-k dielectric materials, perovskites, and high conductivity materials, metals.

26. The method of claim 22, wherein the plurality of ionized particles is accelerated by the electric field to form a coating on a substrate.
